(19) United States
(12) Patent Application Publication
(10) Pub. No.: US 2015/0053261 A1
(43) Pub. Date: Feb. 26, 2015

(54) SOLAR CELL

(71) Applicants: Ryuta Tsuchiya, Tokyo (JP); Keiji Watanabe, Tokyo (JP); Takashi Hattori, Tokyo (JP); Mieko Matsumura, Tokyo (JP)

(72) Inventors: Ryuta Tsuchiya, Tokyo (JP); Keiji Watanabe, Tokyo (JP); Takashi Hattori, Tokyo (JP); Mieko Matsumura, Tokyo (JP)

(73) Assignee: HITACHI, LTD., Tokyo (JP)

(21) Appl. No.: 14/239,612

(22) PCT Filed: Aug. 29, 2011
(86) PCT No.: PCT/JP2011/069490

§ 371 Date: Oct. 23, 2014

(51) Int. Cl. H01L 31/0352; H01L 31/0328

(52) U.S. Cl. CPC H01L 31/035254; H01L 31/035227; H01L 31/0328
USPC 136/256

(57) ABSTRACT

A surface reflectivity of a solar cell is reduced by applying a nanopillar array including a plurality of nanopillars to the solar cell. Further, by constituting the nanopillars with a Si/SiGe superlattice and controlling a Ge composition ratio of a SiGe layer (2), excited electron and hole are spatially separated in different layers, thus increasing a carrier lifetime, and at the same time, an optical-electrical conversion efficiency is improved by a multi-exciton phenomenon due to a quantum confinement effect. In addition, by forming an intermediate band by thinning a Si layer (1) and the SiGe layer (2), a carrier extraction efficiency is improved.

### TECHNICAL FIELD

The present invention relates to a solar cell, and more particularly, to a technology to be effectively applied to a solar cell using a superlattice structure (super structure and ordered lattice structure).

### BACKGROUND ART

Transmission loss and quantum loss occupy a large proportion of a loss of a solar cell. The transmission loss is a loss generated due to transmission of light having energy smaller than a bandgap of material constituting the solar cell through the material without being absorbed by the material among solar light inputted to the solar cell. On the other hand, among the inputted solar light, light having energy larger than the bandgap of the material constituting the solar cell is absorbed inside the solar cell to generate a carrier. However, a surplus energy exceeding the bandgap is dissipated as a heat. This is the quantum loss. When the solar energy is assumed to be 100%, each of the transmission loss and the quantum loss takes about 20% to 30%.

In order to suppress the transmission loss, it is effective to control the bandgap of the material that constitutes the solar cell to use a wavelength of a broad bandwidth of the solar light. Further, it is also effective to form a corrugated structure smaller than a wavelength (wavelength of visible light (400 nm to 800 nm)) of the solar light, i.e., a sub-wavelength structure, on a surface of the solar cell, thus using an optical confinement effect as well as an antireflection effect.

On the other hand, in order to reduce the quantum loss, for example, it is effective to use a multi-exciton phenomenon using a quantum effect. The multi-exciton phenomenon refers to a phenomenon that a plurality of excitons is generated with respect to an absorbed photon. In the case of a normal solar cell, one electron-hole pair is generated with respect to one absorbed photon of the solar light energy; however, by using the multi-exciton phenomenon, two or more electron-hole pairs can be generated with respect to one absorbed photon of the solar light energy.

In order to develop the multi-exciton phenomenon, it is required to use quantum effect, such as “quantum size effect (quantum confinement effect generated by a quantum well structure or a quantum dot)”, “intermediate band”, or “increase of carrier energy relaxation time”. If this quantum effect is used so that the quantum loss can be reduced by using the high-energy solar light, for example, as described in M. C. Hanna and A. J. Nozik, “Solar conversion efficiency of photovoltaic and photoelectrolysis cells with carrier multiplication absorbers”, Journal of Applied Physics 100, 074510 (2006) (NPL 1), the theoretical limit of the energy conversion efficiency can be expected to be equal to or more than 40%.

Further, R. D. Schaller and V. I. Klimov, “High Efficiency Carrier Multiplication in PbSe Nanocrystals: Implications for Solar Energy Conversion”, Physical Review Letters Vol. 92, 186601 (2004) (NPL 2), describes that the multi-exciton phenomenon of generating two or more electron-hole pairs with respect to one high-energy photon has been observed in a PbSe dot or in a PbS dot.

Moreover, J. Tang, at al., “Quantum Dot Photovoltaics in the Extreme Quantum Confinement Regime: The Surface-Chemical Origins of Exceptional Air-and Light-Stability”, American Chemical Society Nano, Vol. 4, No. 2, 869-878 (2010) (NPL 3) describes a structure of a solar cell using a quantum dot.

In addition, M. C. Beard, et al., “Multiple Exciton Generation in Colloidal Silicon Nanocrystals”, American Chemical Society Nano Letters, Vol. 7, No. 8, 2506-2512 (2007) (NPL 4) describes that, in the case of using a Si quantum dot, the multi-exciton phenomenon has been observed in a short wavelength region of 400 nm or shorter.

### CITATION LIST

### Non-Patent Literature

NPL 1: M. C. Hanna and A. J. Nozik, “Solar conversion efficiency of photovoltaic and photoelectrolysis cells with carrier multiplication absorbers”, Journal of Applied Physics 100, 074510 (2006)
NPL 2: R. D. Schaller and V. I. Klimov, “High Efficiency Carrier Multiplication in PbSe Nanocrystals: Implications for Solar Energy Conversion”, Physical Review Letters Vol. 92, 186601 (2004)
NPL 3: J. Tang, et al., “Quantum Dot Photovoltaics in the Extreme Quantum Confinement Regime: The Surface-Chemical Origins of Exceptional Air-and Light-Stability”, American Chemical Society Nano, Vol. 4, No. 2, 869-878 (2010)
NPL 4: M. C. Beard, et al., “Multiple Exciton Generation in Colloidal Silicon Nanocrystals”, American Chemical Society Nano Letters, Vol. 7, No. 8, 2506-2512 (2007)

### SUMMARY OF INVENTION

### Technical Problem

In recent years, a solar cell using the quantum confinement effect generated by a quantum dot (semiconductor nanocrystal having a diameter equal to or smaller than a de Broglie wavelength (about 10 nm) has been proposed. For example, in the above-mentioned NPL 2, it is described that the multi-exciton phenomenon of generating two or more electron-hole pairs with respect to one high-energy photon has been observed in a PbSe dot or in a PbS dot. However, in the solar cell using the quantum dot, when a carrier generated in the quantum dot is extracted to outside, it is required to use a tunnel current between the quantum dots, and hence there is a problem that the carrier extraction efficiency is low.

A structure of the solar cell using the quantum dot is described, for example, in the above-mentioned NPL 3 or the like. For example, the solar cell using the quantum dot has a structure including a transparent conductive film formed on a glass substrate, a quantum dot formed on the transparent conductive film by using a coating process or the like, and an electrode formed on the quantum dot. Alternatively, the solar cell using the quantum dot may have a structure including a Si dot (quantum dot) formed on a Si substrate, an antireflection layer formed on the Si dot, and a surface electrode formed on the antireflection layer. The above-mentioned Si dot is formed by a thermal treatment, after laminating a stoichiometric SiO₂ layer and a Si-rich SiₓO_{y} (x/y>0.5) layer in an alternate manner, centering around the Si-rich SiₓO_{y} (x/y>0.5) layer.

However, even with the solar cell using the quantum dot of either structure, it is difficult to form a corrugated structure smaller than the wavelength of the solar light, i.e., a so-called sub-wavelength structure, on a surface of the solar cell, and hence the optical confinement effect with the antireflection effect cannot be used.

It is an object of the present invention to provide a technology with which improvements of the carrier extraction efficiency and the optical confinement effect can be achieved in a solar cell having the quantum confinement effect.

The above and other objects and new features of the present invention will be better understood by reading the detailed description of the specification in connection with the accompanying drawings.

### Solution to Problem

Among embodiments of the present invention disclosed in this application, a brief summary of some representatives is as follows.

The present invention relates to a solar cell including a p-type semiconductor substrate including a first surface and a second surface opposite to the first surface, a p-type semiconductor layer formed on the first surface of the semiconductor substrate, a nanopillar array formed on the p-type semiconductor layer and including a plurality of nanopillars arranged at predetermined intervals and connected to the p-type semiconductor layer, an inter-layer insulation film formed between adjacent nanopillars of the plurality of nanopillars, an n-type semiconductor layer formed on the nanopillar array and the inter-layer insulation film and connected to the plurality of nanopillars, a passivation film formed on the n-type semiconductor layer, a first electrode formed on the passivation film, penetrating through the passivation film, and electrically connected to the n-type semiconductor layer, and a second electrode formed on the second surface of the semiconductor substrate and electrically connected to the semiconductor substrate, where the plurality of nanopillars is constituted with a Si/SiGe superlattice including Si layers and SiGe layers alternately laminated.

Further, the present invention relates to a solar cell including a p-type semiconductor substrate including a first surface and a second surface opposite to the first surface, a p-type semiconductor layer formed on the first surface of the semiconductor substrate, a nanopillar array formed on the p-type semiconductor layer and including a plurality of nanopillars arranged at predetermined intervals and connected to the p-type semiconductor layer, a plurality of n-type semiconductor layers formed respectively on upper surfaces of plurality of nanopillars and connected to the plurality of nanopillars, an inter-layer insulation film formed between adjacent nanopillars of the plurality of nanopillars and adjacent n-type semiconductor layers of the plurality of n-type semiconductor layers, a transparent conductive film formed on the plurality of n-type semiconductor layers and the inter-layer insulation film and connected to the plurality of n-type semiconductor layers, a first electrode formed on the transparent conductive film and electrically connected to the transparent conductive film, and a second electrode formed on the second surface of the semiconductor substrate and electrically connected to the semiconductor substrate, where the plurality of nanopillars is constituted with a Si/SiGe superlattice including Si layers and SiGe layers alternately laminated.

Moreover, the present invention relates to a solar cell including a p-type semiconductor substrate including a first surface and a second surface opposite to the first surface, a nanopillar array formed on the first surface of the semiconductor substrate and including a plurality of nanopillars arranged at predetermined intervals and connected to the semiconductor substrate, an inter-layer insulation film formed on side surfaces of the plurality of nanopillars, a via hole formed penetrating through the semiconductor substrate from the first surface to the second surface in an area where the nanopillar array is not formed, a p-type semiconductor layer covering the plurality of nanopillars and the inter-layer insulation film, formed on an exposed portion of the first primary surface of the semiconductor substrate, a side surface of the via hole, and a portion of the second primary surface of the semiconductor substrate surrounding the via hole, and connected to the semiconductor substrate, an n-type semiconductor layer formed on the second primary surface of the semiconductor substrate and connected to the semiconductor substrate without being connected to the p-type semiconductor layer, a passivation film covering the n-type semiconductor layer and formed on the second primary surface of the semiconductor substrate, a third electrode formed on the passivation film, penetrating through a first contact hole formed on the passivation film, and electrically connected to the n-type semiconductor layer, and a fourth electrode formed on the passivation film, penetrating through a second contact hole formed on the passivation film, and electrically connected to the p-type semiconductor layer, where the nanopillar array is formed on a side of the first primary surface of the semiconductor substrate, the third electrode and the fourth electrode are formed on a side of the second primary surface of the semiconductor substrate, and the plurality of nanopillars is constituted with a Si/SiGe superlattice including Si layers and SiGe layers alternately laminated.

### Advantageous Effects of Invention

Among embodiments of the present invention disclosed in this application, a brief summary of an advantageous effect obtained by some representatives is as follows.

In a solar cell having a quantum confinement effect, improvements in carrier extraction efficiency and high light confinement effect can be achieved.

### BRIEF DESCRIPTION OF DRAWINGS

FIG. 1 is a cross-sectional view of relevant parts of a solar cell according to Example 1 of the present invention.

FIG. 2 is a cross-sectional view of relevant parts of a solar cell according to Example 2 of the present invention.

FIG. 3 is a cross-sectional view of relevant parts of a solar cell according to Example 3 of the present invention.

FIG. 4 is a cross-sectional view of relevant parts of a solar cell according to Example 4 of the present invention.

FIG. 5 is a cross-sectional view of relevant parts of a solar cell according to Example 5 of the present invention.

FIG. 6 is a graph showing results of light reflectivity measurements of a nanopillar array and a silicon texture structure.

FIG. 7 is a graph showing energy spectra of the solar light.

FIG. 8 is a transmission electron microscope image showing an example of a cross section of a Si/SiGe superlattice.

FIG. 9 is a graph showing X-ray diffraction spectra of the Si/SiGe superlattice.

FIG. 10(a) and FIG. 10(b) are schematic diagrams illustrating a band structure of a Si/Si_{0.7}Ge_{0.3} superlattice and a band structure of a Si/Si_{0.9}Ge_{0.1} superlattice, respectively.

FIG. 11 is a schematic diagram illustrating a principle for determining whether the Si/SiGe superlattice has a type-I superlattice structure or a type-II superlattice structure.

FIG. 12 (a) and FIG. 12(b) are graphs showing excitation light intensities of photoluminescence spectra measured with a Si/SiGe superlattice having a SiGe layer of Si_{0.7}Ge_{0.3} composition and excitation light intensities of photoluminescence spectra measured with a Si/SiGe superlattice having a SiGe layer of Si_{0.9}Ge_{0.1} composition, respectively.

### DESCRIPTION OF EMBODIMENTS

In the following embodiments, if necessary for convenience, descriptions are given in a plurality of sections or embodiments; however, unless otherwise particularly specified, those sections or embodiments are not irrelevant to each other but one has a relationship with the other of being a modification example of whole or a part, a detailed description, a supplemental description, or the like of the other.

Further, in the following embodiments, when referring to the number of elements or the like (including number of pieces, numerical value, quantity, range, and the like), unless otherwise particularly specified or obviously limited to a specific value in principle, it should not be construed to be limited to the specific value but be construed to be equal to or larger than the specific value or equal to or smaller than the specific value. Moreover, in the following embodiments, unless otherwise particularly specified or obviously considered to be essential in principle, it goes without saying that the constituent elements (including constituent steps and the like) are not necessarily essential. Similarly, in the following embodiments, when referring to shapes and positional relationships of the constituent elements or the like, unless otherwise particularly specified or obviously considered not to be so in principle, it should be construed to include one substantially approximated or similar to the shape or the like. The same goes for the above-mentioned numerical value and the range.

Further, in the drawings used in the following embodiments, even on a plan view, a hatching may be used for an easy view of the drawing.

Moreover, in the entire drawings for describing the following embodiments, ones having similar functions are assigned with the same reference sign, and a repeated description thereof is omitted. Exemplary embodiments of the present invention are described in detail below with reference to the accompanying drawings.

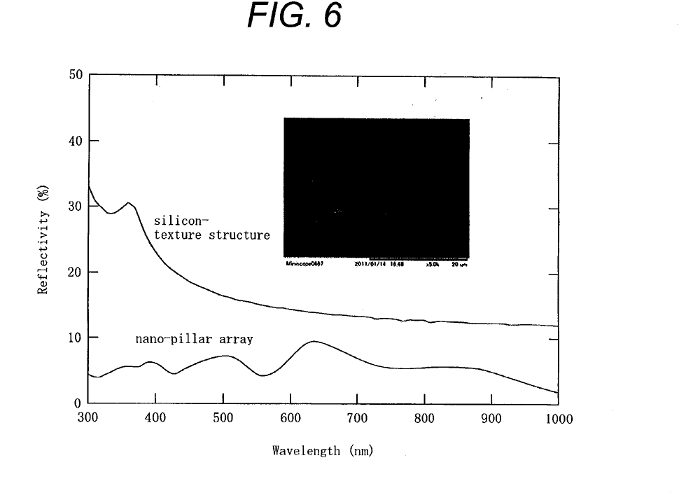

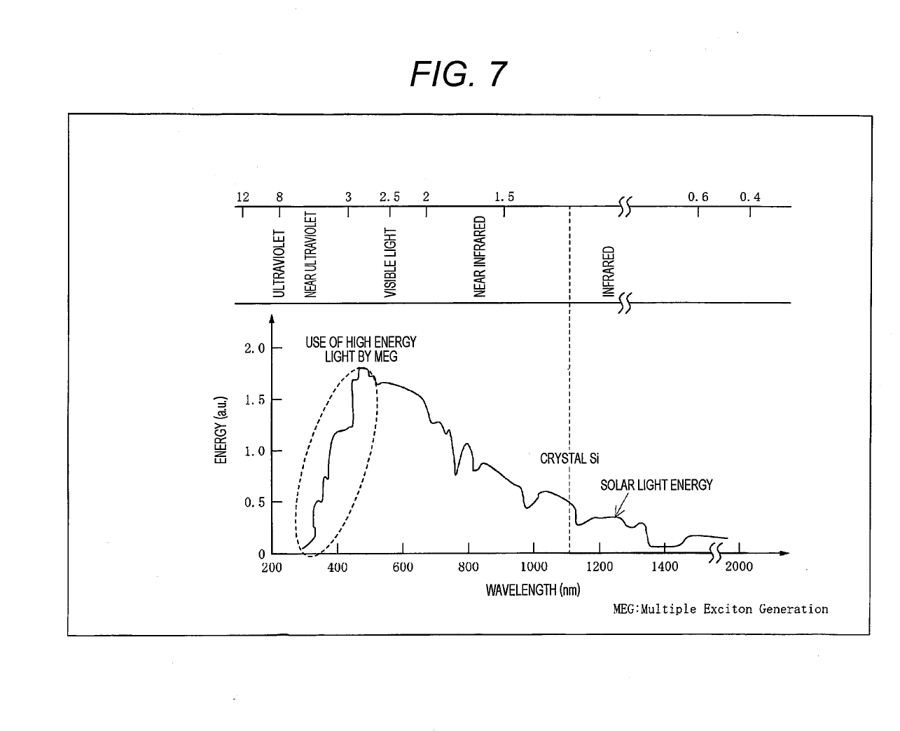

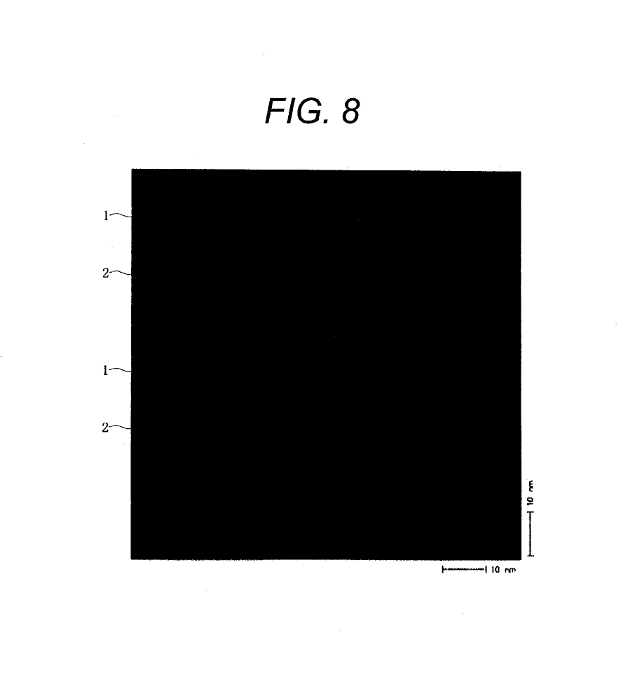

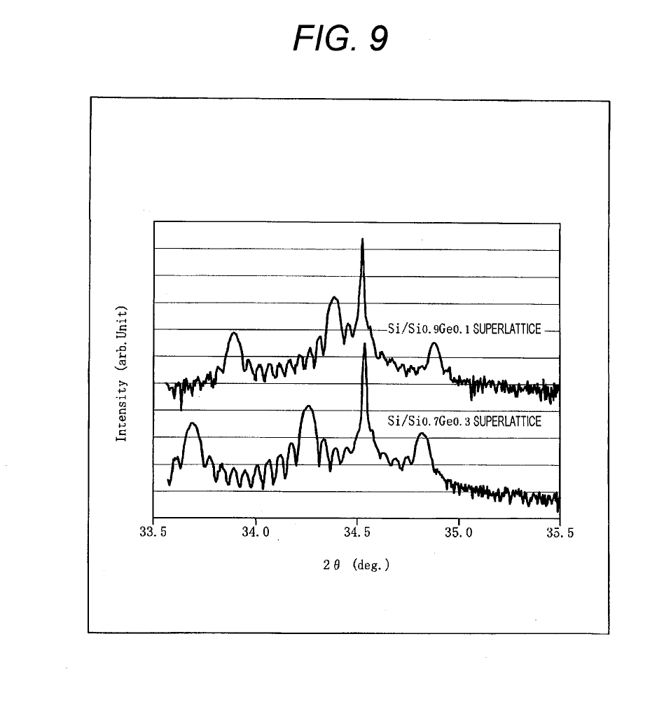

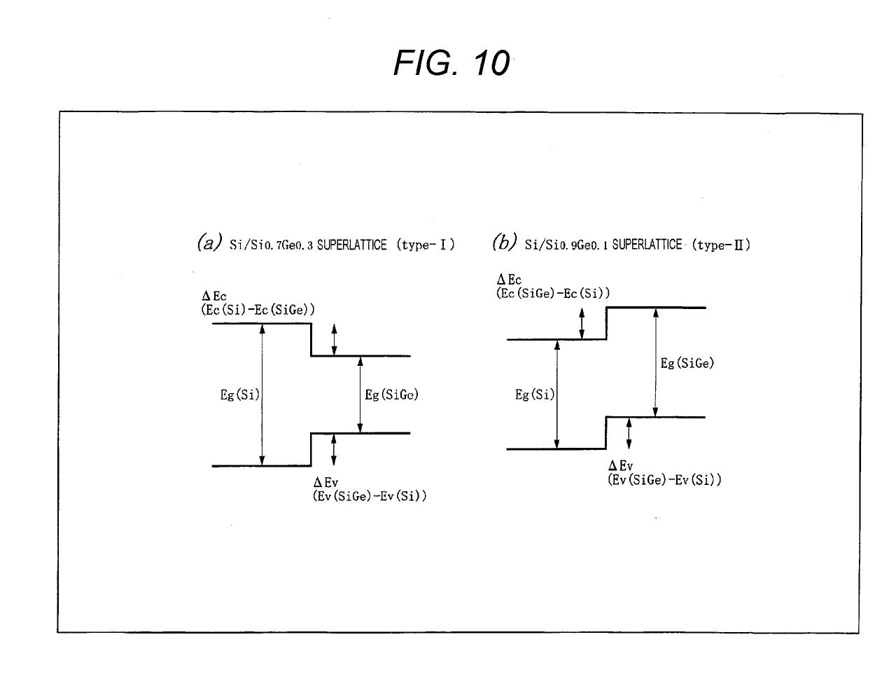

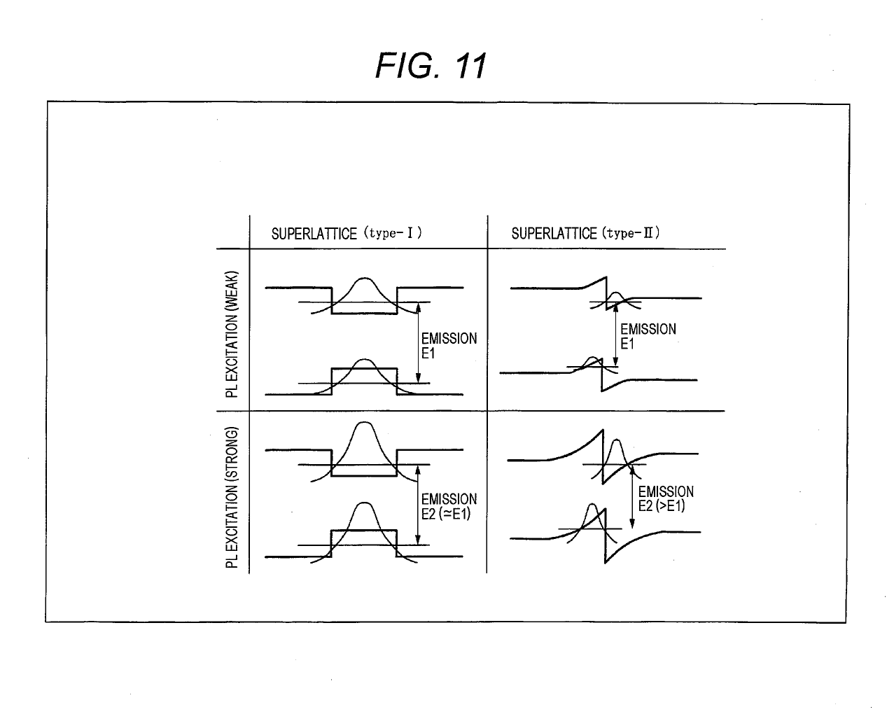

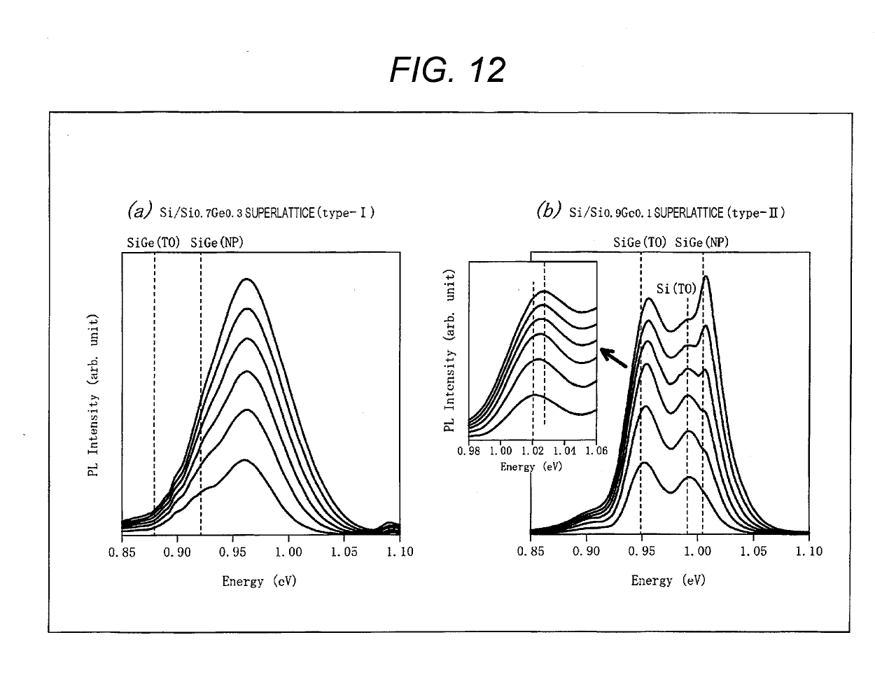

Firstly, various phenomena generated in a superlattice including Si (silicon) layers and SiGe (silicon germanium) layers laminated in an alternate manner (hereinafter, referred to as a Si/SiGe superlattice) found by the inventors of the present invention are described in detail with reference to FIGS. 6 to 12. FIG. 6 is a graph showing results of light reflectivity measurements of a nanopillar array and a silicon texture structure, FIG. 7 is a graph showing energy spectra of the solar light, FIG. 8 is a transmission electron microscope image showing an example of a cross section of the Si/SiGe superlattice, FIG. 9 is a graph showing X-ray diffraction spectra of the Si/SiGe superlattice, FIG. 10(a) and FIG. 10(b) are schematic diagrams illustrating a band structure of a Si/Si_{0.7}Ge_{0.3} superlattice and a band structure of a Si/Si_{0.9}Ge_{0.1} superlattice, respectively, FIG. 11 is a schematic diagram illustrating a principle for determining whether the Si/SiGe superlattice has a type-I superlattice structure or a type-II superlattice structure, and FIG. 12 (a) and FIG. 12(b) are graphs showing excitation light intensities of photoluminescence spectra measured with a Si/SiGe superlattice having a SiGe layer of Si_{0.7}Ge_{0.3} composition and excitation light intensities of photoluminescence spectra measured with a Si/SiGe superlattice having a SiGe layer of Si_{0.9}Ge_{0.1} composition, respectively.

A result of light reflectivity measurement of the nanopillar array is shown in FIG. 6. The nanopillar mentioned here refers to a columnar structure having a diameter smaller than the wavelength of the solar light. The nanopillar array refers to a two-dimensional array of a plurality of nanopillars with a predetermined interval. The diameter of the nanopillar constituting the nanopillar array is, for example, in a range from 10 nm to 120 nm, preferably a peripheral range with the center value of 30 nm. Further, the plurality of nanopillars can be arranged at equal intervals or arranged at different intervals. In addition, the shape of the nanopillar is not limited to a circular column but can be other columnar shape such as a rectangular column.

By employing the nanopillar array, it has been known that the reflectivity can be reduced to 10% or lower in a wavelength region of 300 nm to 1000 nm. In order to use the multi-exciton phenomenon, in particular, it is important to reduce the reflectivity in a wavelength region of high solar light energy, i.e., in a short wavelength region of 400 nm or shorter. For example, in the above-mentioned NPL 4, in the case of using a Si quantum dot, it is described that the multi-exciton phenomenon has been observed in the short wavelength region of 400 nm or shorter.

For comparison, a light reflectivity measurement result of a silicon texture structure (a structure having a surface with a small corrugated shape) is shown in FIG. 6. The silicon texture structure is formed, for example, by using an alkali etching. In the case of the silicon texture structure, the reflectivity at the wavelength of 400 nm is about 28%, and it is clear that the reflectivity can be reduced considerably by employing the nanopillar array.

The energy spectra of the solar light are shown in FIG. 7. As shown in FIG. 7, the solar light has a high energy in the short wavelength region of 400 nm or shorter. Therefore, the nanopillar array can more effectively use the solar light of the short wavelength region of 400 nm or shorter, which is necessitated to generate the multi-exciton, compared to the silicon texture structure.

The nanopillar is constituted with a Si/SiGe superlattice. An example of a transmission electron microscope image of a cross section of the Si/SiGe superlattice is shown in FIG. 8. The Si/SiGe superlattice shown in FIG. 8 is formed by controlling a composition ratio of Ge (germanium) by using a selective epitaxial growth method. A thickness of each of a Si layer 1 and a SiGe layer 2 is, for example, equal to or thinner than 10 nm, preferably a peripheral range with the center value of 5 nm.

FIG. 9 is a graph showing XRD (X-Ray Diffraction) measurement results of a Si/SiGe superlattice having a SiGe layer of Si_{0.9}Ge_{0.1} composition (hereinafter, referred to as a Si/Si_{0.7}Ge_{0.3} superlattice) and a Si/SiGe superlattice having a SiGe layer of Si_{0.7}Ge_{0.3} composition (hereinafter, referred to as a Si/Si_{0.9}Ge_{0.1} superlattice). In either case, a diffraction pattern due to the Si/SiGe superlattice is obtained, and a position of a diffraction peak finds that the Ge composition ratio is well controlled.

A band structure in the Si/SiGe superlattice is changed when the Ge composition ratio of the SiGe layer is changed. In the Si/SiGe superlattice, a superlattice system of a type in which conduction bands and valance bands of adjacent semiconductors (Si and SiGe) are respectively overlapped with each other and energy gap areas exist being partially overlapped with each other is defined as a type-I superlattice structure. In contrast to this, a superlattice system of a type in which a conduction band of one semiconductor and a valance band of the other semiconductor are overlapped with each other is defined as a type-II superlattice structure. For example, the above-mentioned Si/Si_{0.7}Ge_{0.3} superlattice is the type-I superlattice structure, and the above-mentioned Si/Si_{0.9}Ge_{0.1} superlattice is the type-II superlattice structure.

A band structure of the type-I superlattice structure (Si/Si_{0.7}Ge_{0.3} superlattice) is illustrated in FIG. 10(a), and a band structure of the type-II superlattice structure (Si/Si_{0.9}Ge_{0.1} superlattice) is illustrated in FIG. 10(b).

As illustrated in FIG. 10(a), in the case of the type-I superlattice structure, excited electrons and holes are concentrated in a quantum well layer formed by a narrow bandgap. Because the carriers are confined in the same area of the quantum well layer, a recombination can be performed with high efficiency. That is, the emission characteristic is improved by the recombination of the carriers with a short carrier lifetime. Therefore, the type-I superlattice structure is suitable for an exciton device such as a semiconductor laser.

On the other hand, in the case of the solar cell, the excited electrons and holes need to be extracted separately from each other. That is, it is important how to suppress the recombination of the carriers and how to increase the carrier lifetime, in order to improve the optical-electrical conversion efficiency.

As illustrated in FIG. 10(b), in the case of the type-II superlattice structure, the excited electrons and holes are spatially separated from each other to different layers (the Si layer or the SiGe layer). With this mechanism, a probability of the carrier recombination is decreased, so that the carrier lifetime can be increased. As a result, the extraction of the carriers can be performed with high efficiency. Therefore, the Si/SiGe superlattice of the type-II superlattice structure is suitable for the solar cell. In the Si/SiGe superlattice, the type-I superlattice structure or the type-II superlattice structure can be selectively formed by controlling the Ge composition ratio.

A method of determining whether the Si/SiGe superlattice is a type-I superlattice structure or a type-II superlattice structure is described. The method employs an excitation light intensity of photoluminescence spectra of the Si/SiGe superlattice.

Firstly, a principle when determining whether the Si/SiGe superlattice is a type-I superlattice structure or a type-II superlattice structure is described with reference to FIG. 11. The number of electrons in the conduction band and the number of holes in the valance band generated by an absorption of light are changed by changing the excitation light intensity. However, in the case of the type-I superlattice structure in which the electrons and the holes exist in the same layer, the band structure and the emission energy of the photoluminescence spectra do not virtually depend on the number of carriers.

In contrast to this, in the case of the type-II superlattice structure, because the electrons and the holes separately exist in different layers from each other, they are attracted to a boundary surface due to a coulomb interaction. In this case, a bending of the band is generated near the boundary surface, and the carriers near the boundary surface exist in a quantum level of a triangular potential. When the bending of the band is made steep by a strong excitation, the quantum confinement effect is increased, so that the quantum level is shifted to a high energy side. Therefore, in the case of the type-II superlattice structure, the emission energy of the photoluminescence spectra is shifted to the high energy side due to an increase of the excitation light intensity.

Results of actual investigation of an excitation light intensity dependency of the photoluminescence spectra for the Si/Si_{0.7}Ge_{0.3} superlattice and the Si/Si_{0.9}Ge_{0.1} superlattice are shown in FIG. 12. As shown in FIG. 12(a), in the Si/Si_{0.7}Ge_{0.3} superlattice (type-I superlattice structure), no peak shift of the emission energy is observed due to the excitation light intensity. On the other hand, as shown in FIG. 12(b), in the Si/Si_{0.9}Ge_{0.1} superlattice (type-II superlattice structure), a SiGe (TO) peak is shifted to the high energy side along with a strong excitation. In this manner, by investigating the excitation light intensity of the photoluminescence spectra of the Si/SiGe superlattice, it is possible to determine whether the Si/SiGe superlattice is a type-I superlattice structure or a type-II superlattice structure.

As described above, the Si/SiGe superlattice of the type-II superlattice structure, which is suitable for the solar cell, can be manufactured by controlling the Ge composition ratio of the SiGe layer. In order to achieve the Si/SiGe superlattice of the type-II superlattice structure, it is preferred that the Ge composition ratio of the SiGe layer in the Si/SiGe superlattice be equal to or smaller than 0.3. Further, no impurity is doped in the Si layer and the SiGe layer. When an impurity is doped, Fermi levels of the Si layer and the SiGe layer are changed depending on the doping amount of the impurity, and hence it becomes difficult to manipulate a band engineering. In addition, if impurity concentrations of the Si layer and the SiGe layer are increased, the carrier lifetime is decreased. From these aspects, it is preferred not to dope any impurity in the Si layer and the SiGe layer.

A method of extracting a generated carrier from a superlattice structure including the Si/SiGe superlattice is described below.

In the case of the quantum dot, for example, it is often the case that a nanodot (for example, a nanocrystal having a diameter of 1 nm to 5 nm) is buried in a barrier layer including SiO₂ (silicon dioxide), SiN (silicon nitride), SiC (silicon carbide), or the like. However, because SiO₂, SiN, or SiC has a high potential barrier, a current can hardly flow between the quantum dots.

On the other hand, in the Si/SiGe superlattice according to the present invention, as illustrated in FIG. 11, the potential barrier can be lowered by controlling the bending of the band. Further, by thinning the thickness of each of the Si layer and the SiGe layer to about 5 nm to 6 nm, a formation of an intermediate band can be expected due to an electronic coupling between the Si layer and the SiGe layer. In this case, the excited electrons and holes become capable of moving in the intermediate band at high speed through a tunnel. Therefore, in the type-II superlattice structure, the electrons and the holes, which are spatially separated from each other, flow through the intermediate band, by which the carrier extraction efficiency can be considerably increased.

The contents mentioned above are summarized below. The reflectivity of the solar light on the surface of the solar cell can be reduced by employing a nanopillar array. In particular, by employing the nanopillar array, the solar light in the short wavelength region of 400 nm or shorter, which is necessitated to generate the multi-exciton, can be effectively used.

Further, by forming a plurality of nanopillars constituting the nanopillar array with the Si/SiGe superlattice and making the Si/SiGe superlattice a type-II superlattice structure by controlling the Ge composition ratio of the SiGe layer, the carrier lifetime can be increased, and hence, the optical-electrical conversion efficiency of the solar cell can be improved. Moreover, the quantum confinement effect can be increased in the Si/SiGe superlattice by processing the plurality of nanopillars to be thin, and hence the optical-electrical conversion efficiency can be further improved due to the multi-exciton phenomenon. The improvement of the optical-electrical conversion efficiency due to the multi-exciton phenomenon increases the number of carriers, thus increasing a short-circuit current (current flowing when short circuited at the time of being irradiated with the light) in the solar cell characteristics.

In addition, by forming an intermediate band due to the electronic coupling between the Si layer and the SiGe layer by thinning the thickness of each of the Si layer and the SiGe layer, the excited electrons and holes can move in the intermediate band at high speed through a tunnel, so that the carrier extraction efficiency can be considerably increased.

From these aspects, according to the present invention, high carrier extraction efficiency and high optical confinement effect can be achieved in a solar cell having the quantum confinement effect.

### Example 1

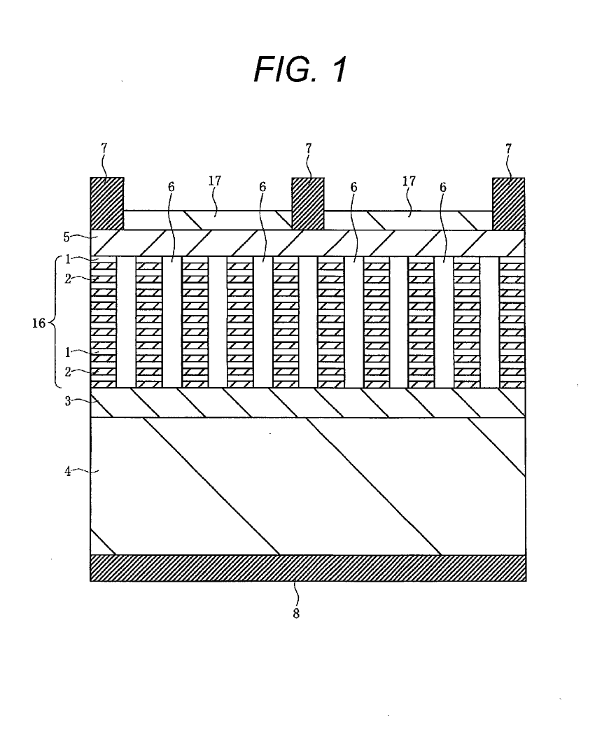

A solar cell according to Example 1 of the present invention is described with reference to a cross-sectional view of relevant parts of a solar cell illustrated in FIG. 1.

The feature of the structure of the solar cell according to Example 1 is to include a nanopillar array including a plurality of nanopillars (hereinafter, referred to as Si/SiGe nanopillars) constituted with a Si/SiGe superlattice including Si layers 1 and SiGe layers 2 laminated in an alternate manner arranged in a two-dimensional array on a primary surface of a p-type semiconductor substrate 4.

For example, a p-type semiconductor layer 3 is formed on the primary surface (front surface, first surface) of the p-type semiconductor substrate 4 formed of a Si single crystal. An impurity concentration of the p-type semiconductor layer 3 is higher than that of the semiconductor substrate 4, which is, for example, about 10¹⁸ cm⁻³ to 10²⁰ cm⁻³. The p-type semiconductor layer 3 can be formed by an impurity diffusion method such as an ion implantation method, a vapor-phase diffusion method, a solid-phase diffusion method, or the like, or formed by a deposition method such as a CVD (Chemical Vapor Deposition) method, a sputtering method, an evaporation method, or the like. A thickness of the semiconductor substrate 4 is, for example, equal to or thinner than 200 nm, and a thickness of the p-type semiconductor layer 3 is, for example, 50 nm to 100 nm.

A nanopillar array area 16 exists on the p-type semiconductor layer 3. A nanopillar array including a plurality of circular column-shaped Si/SiGe nanopillars each constituted with a Si/SiGe superlattice including the Si layers 1 and the SiGe layers 2 laminated in an alternate manner arranged at predetermined intervals in a two-dimensional array is formed in the nanopillar array area 16. A thickness of each of the Si layer 1 and the SiGe layer 2 is, for example, 5 nm to 6 nm, and a thickness of the nanopillar array area 16 is, for example, 200 nm. A diameter of the Si/SiGe nanopillar is, for example, 30 nm, and an interval between adjacent Si/SiGe nanopillars is, for example, 30 nm.

The Si/SiGe nanopillar can be manufactured, for example, in the following manner.

Firstly, the Si layer 1 and the SiGe layer 2 constituting the Si/SiGe nanopillar are formed on the p-type semiconductor layer 3 in an alternate manner by using, for example, the selective epitaxial growth method. Each of the Si layer 1 and the SiGe layer 2 is formed by controlling the Ge composition ratio at the time of growth. Alternatively, the Si layer 1 and the SiGe layer 2 may be deposited on the p-type semiconductor layer 3 in an alternate manner by using a deposition method such as the CVD method, the sputtering method, or the evaporation method, and then the Si layer 1 and the SiGe layer 2 may be crystallized by a thermal treatment to form the Si layer 1 and the SiGe layer 2 constituting the Si/SiGe nanopillar.

Subsequently, a multilayer film including the Si layer 1 and the SiGe layer 2 is processed by, for example, etching with a pattern formed by an electron beam lithography as a mask, etching with a pattern formed by a lithography using ArF (argon fluoride), KrF (krypton fluoride), or the like as a mask, or etching with a nanoimprint or a nanoparticle as a mask, to form a plurality of Si/SiGe nanopillars.

No impurity is doped in the Si layer 1 and the SiGe layer 2. If an impurity is doped, the Fermi levels of the Si layer 1 and the SiGe layer 2 are changed depending on the doping amount of the impurity, and hence it becomes difficult to manipulate the band engineering. In addition, if the impurity concentrations of the Si layer 1 and the SiGe layer 2 are increased, the carrier lifetime is decreased. Therefore, it is preferred not to dope any impurity in the Si layer 1 and the SiGe layer 2.

Further, an inter-layer insulation film 6 is formed between adjacent Si/SiGe nanopillars. The inter-layer insulation film 6 is formed of, for example, SiO₂, SiN, SiC, or the like. The inter-layer insulation film 6 is formed by, for example, depositing the film to cover the plurality of Si/SiGe nanopillars by a deposition method such as the CVD method, the sputtering method, or the evaporation method, and then planarizing a surface of the film by a mechanical polishing method such as a CMP (Chemical Mechanical Polishing) or the like or an etching-back method. Alternatively, the inter-layer insulation film 6 may be formed by embedding a highly fluidic insulation film such as a SOG (Spin On Glass) or the like between the plurality of Si/SiGe nanopillars by a coating method.

In order to suppress a carrier recombination generated at a boundary surface of the Si/SiGe nanopillars and the inter-layer insulation film 6, a quality insulation film (not shown) may be formed on surfaces of the Si/SiGe nanopillars by performing an oxidation process before forming the inter-layer insulation film 6. By performing the oxidation process, defects of the Si/SiGe nanopillars can be reduced on the boundary surface of the Si/SiGe nanopillars and the inter-layer insulation film 6, and hence the carrier recombination can be suppressed.

An n-type semiconductor layer 5 is formed on the nanopillar array area 16 (the nanopillar array and the inter-layer insulation film 6). The n-type semiconductor layer 5 is constituted with, for example, single crystal Si or polycrystal Si, and its impurity concentration is, for example, 10¹⁸ cm⁻³ to 10²⁰ cm⁻³. A thickness of the n-type semiconductor layer 5 is, for example, 50 nm to 100 nm. The n-type semiconductor layer 5 is formed by a deposition method such as the CVD method, the sputtering method, or the evaporation method. Alternatively, the n-type semiconductor layer 5 may be formed by an ion implantation method.

A passivation film 17 is formed on the n-type semiconductor layer 5. The passivation film 17 has a function of suppressing a surface carrier recombination and a surface reflectivity on a surface of the n-type semiconductor layer 5. The passivation film 17 is constituted with, for example, SiO₂, SiN, or the like.

Further, a front surface electrode 7 patterned and electrically connected to the n-type semiconductor layer 5 is formed, and a back surface electrode 8 electrically connected to a back surface of the p-type semiconductor substrate 4 is formed on a back surface (second surface) of the p-type semiconductor substrate 4. The front surface electrode 7 and the back surface electrode 8 are constituted with, for example, Al (aluminum), Ag (silver), or the like.

In this manner, in the solar cell according to Example 1, the reflectivity of the solar light at the surface of the solar cell in the wavelength region of 300 nm to 1000 nm can be reduced by employing the nanopillar array. In particular, the solar light in the short wavelength region of 400 nm or shorter, which is necessitated to use the multi-exciton phenomenon, can be more effectively used.

Further, by forming the nanopillar with the Si/SiGe superlattice and making the Si/SiGe superlattice a type-II superlattice structure by controlling the Ge composition ratio of the SiGe layer 2, the excited electrons and holes are spatially separated in different layers from each other, and hence the probability of the carrier recombination is reduced and the long carrier lifetime can be achieved. Moreover, by processing the Si/SiGe superlattice into a thin nanopillar, the quantum confinement effect is increased in the Si/SiGe superlattice, and hence a further improvement of the optical-electrical conversion efficiency can be achieved due to the multi-exciton phenomenon.

In addition, by thinning the thickness of each of the Si layer 1 and the SiGe layer 2, for example, 5 nm to 6 nm, so that the intermediate band is formed due to the electronic coupling between the Si layer 1 and the SiGe layer 2, the excited electrons and holes are caused to move at high speed in the intermediate band through the tunnel, and hence the carrier extraction efficiency can be considerably increased.

From these aspects, according to Example 1, high carrier extraction efficiency and high optical confinement effect can be achieved in a solar cell having the quantum confinement effect.

### Example 2

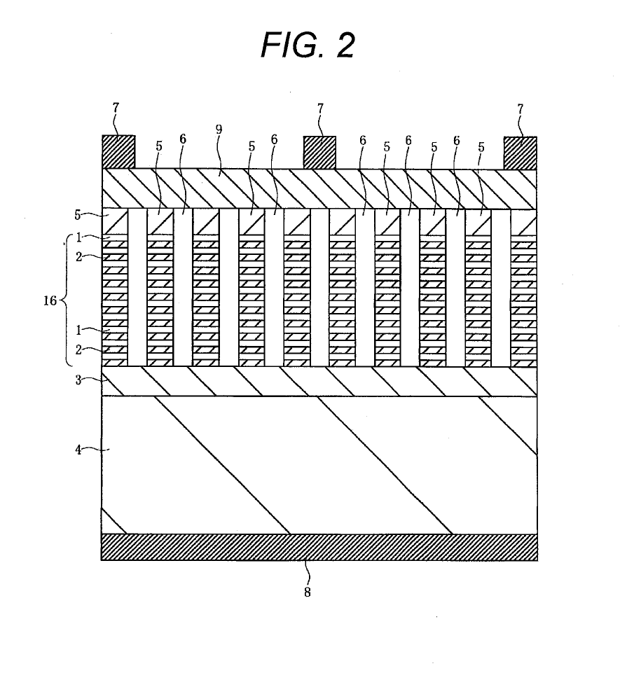

In the above-mentioned solar cell according to Example 1, the n-type semiconductor layer 5 is formed on the entire surface of the nanopillar array area 16 (nanopillar array and the inter-layer insulation film 6). In contrast to this, in a solar cell according to Example 2 of the present invention, an n-type semiconductor layer 5 is formed only on upper surfaces of the plurality of Si/SiGe nanopillars, and the n-type semiconductor layer 5 and a front surface electrode 7 are electrically connected to each other via a transparent conductive film 9 formed on the n-type semiconductor layer 5. The solar cell according to Example 2, which is configured in this manner, is described with reference to a cross-sectional view of relevant parts of the solar cell illustrated in FIG. 2.

In the similar manner to the above-mentioned example 1, for example, a p-type semiconductor layer 3 is formed on the primary surface of a p-type semiconductor substrate 4 formed of a Si single crystal.

A nanopillar array area 16 exists on the p-type semiconductor layer 3. The nanopillar array including a plurality of circular column-shaped Si/SiGe nanopillars each constituted with a Si/SiGe superlattice arranged at predetermined intervals in a two-dimensional array is formed in the nanopillar array area 16. A thickness of each of a Si layer 1 and a SiGe layer 2 is, for example, 5 nm to 6 nm, and a thickness of the nanopillar array area 16 is, for example, 200 nm. A diameter of the Si/SiGe nanopillar is, for example, 30 nm, and an interval between adjacent Si/SiGe nanopillars is, for example, 30 nm. No impurity is doped in the Si layer 1 and the SiGe layer 2.

Further, the n-type semiconductor layer 5 is formed only on the upper surfaces of the plurality of Si/SiGe nanopillars of the nanopillar array area 16. The n-type semiconductor layer 5 is constituted with, for example, single crystal Si or polycrystal Si, and its impurity concentration is, for example, 10¹⁸ cm⁻³ to 10²⁰ cm⁻³. A thickness of the n-type semiconductor layer 5 is, for example, 50 nm to 100 nm.

A laminated structure including the Si/SiGe nanopillars and the n-type semiconductor layer 5 is manufactured, for example, in the following manner.

Firstly, the Si layer 1 and the SiGe layer 2 constituting the Si/SiGe nanopillar are formed on the p-type semiconductor layer 3 in an alternate manner by using, for example, the selective epitaxial growth method. Each of the Si layer 1 and the SiGe layer 2 is formed by controlling the Ge composition ratio at the time of growth. Alternatively, the Si layer 1 and the SiGe layer 2 may be deposited on the p-type semiconductor layer 3 in an alternate manner by using a deposition method such as the CVD method, the sputtering method, or the evaporation method, and then the Si layer 1 and the SiGe layer 2 are crystallized by a thermal treatment to form the Si layer 1 and the SiGe layer 2 constituting the Si/SiGe nanopillar.

Subsequently, the n-type semiconductor layer 5 is formed on the multilayer film including the Si layer 1 and the SiGe layer 2 by a deposition method such as the CVD method, the sputtering method, the evaporation method, or the like.

Thereafter, a multilayer film including the n-type semiconductor layer 5, the Si layer 1 and the SiGe layer 2 is processed by, for example, etching with a pattern formed by an electron beam lithography as a mask, etching with a pattern formed by a lithography using ArF, KrF, or the like as a mask, or etching with a nanoimprint or a nanoparticle as a mask, to form a plurality of Si/SiGe nanopillars on which the n-type semiconductor layer 5 is formed.

Further, an inter-layer insulation film 6 is formed between the laminated structures including the Si/SiGe nanopillars and the n-type semiconductor layer 5. The inter-layer insulation film 6 is formed in the similar manner to that of the above-mentioned example 1. Moreover, in order to suppress a carrier recombination generated at a boundary surface of the Si/SiGe nanopillars and the inter-layer insulation film 6, a quality insulation film (not shown) may be formed on the surfaces of the Si/SiGe nanopillars.

The transparent conductive film 9 is formed on the n-type semiconductor layer 5 and the inter-layer insulation film 6. The transparent conductive film 9 is constituted with, for example, ITO (Indium Tin Oxide), and its thickness is, for example, 1 μm.

Further, the front surface electrode 7 patterned is formed on the transparent conductive film 9, and the n-type semiconductor layer 5 and the front surface electrode 7 are electrically connected to each other via the transparent conductive film 9. A back surface electrode 8 electrically connected to the back surface of the p-type semiconductor substrate 4 is formed on the back surface of the p-type semiconductor substrate 4.

In this manner, the solar cell according to Example 2 has the following effect, in addition to the effect of the solar cell according to the above-mentioned example 1. That is, in the case of the solar cell according to the above-mentioned example 1, the solar light energy is absorbed in the n-type semiconductor layer 5. However, in Example 2, the n-type semiconductor layer 5 is formed only on the upper surfaces of the Si/SiGe nanopillars, and the electrical connection of the front surface electrode 7 and the n-type semiconductor layer 5 is achieved by using the transparent conductive film 9 that is a so-called wide bandgap material, and hence the absorption of the solar light energy by the n-type semiconductor layer 5 can be suppressed. With this configuration, the absorption efficiency of the solar light energy in the Si/SiGe nanopillars can be increased, compared to the above-mentioned example 1, and hence a solar cell having high optical-electrical conversion efficiency can be achieved.

### Example 3

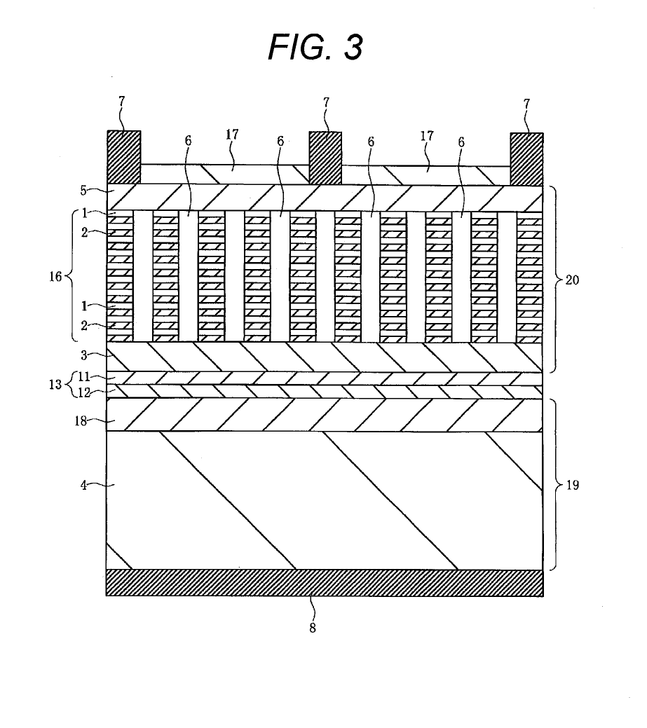

In Example 3 of the present invention, a modification example of the solar cell according to the above-mentioned example 1 is described. In the solar cell according to the above-mentioned example 1, the p-type semiconductor layer 3 is formed on the p-type semiconductor substrate 4. In contrast to this, in a solar cell according to Example 3, an n-layer semiconductor layer 18 having an impurity concentration higher than that of the p-type semiconductor substrate 4 and a tunnel junction layer 13 including an p-layer semiconductor layer 11 and a p-type semiconductor layer 12 are formed between a p-type semiconductor substrate 4 and a p-type semiconductor layer 3. The solar cell according to Example 3 configured in this manner is described with reference to a cross-sectional view of relevant parts of the solar cell illustrated in FIG. 3.

For example, the n-type semiconductor layer 18 having an impurity concentration higher than that of the p-type semiconductor substrate 4 is formed on the primary surface of the p-type semiconductor substrate 4 formed of a Si single crystal. The n-type semiconductor layer 18 may be formed by an impurity diffusion method such as the ion implantation method, the vapor-phase diffusion method, the solid-phase diffusion method, or the like, or by a deposition method such as the CVD method, the sputtering method, the evaporation method, or the like.

The tunnel junction layer 13 including the n-type semiconductor layer 11 and the p-type semiconductor layer is formed on the n-type semiconductor layer 18. A thickness of the tunnel junction layer 13 is, for example, equal to or thinner than 10 nm, and an impurity concentration of each of the n-type semiconductor layer 11 and the p-type semiconductor layer 12 is, for example, 10¹⁹ cm⁻³.

The p-type semiconductor layer 3 is formed on the tunnel junction layer 13. Further, in the similar manner to the above-mentioned example 1, a nanopillar array area 16 constituted with the nanopillar array and an inter-layer insulation film 6 is formed on the p-type semiconductor layer 3, and an n-type semiconductor layer 5 and a passivation film 17 are formed on the nanopillar array area 16.

In addition, a front surface electrode 7 electrically connected to the n-type semiconductor layer 5 is formed, and the back surface electrode 8 electrically connected to the back surface of the p-type semiconductor substrate 4 is formed on the back surface of the p-type semiconductor substrate 4.

In this manner, the solar cell according to Example 3 has the following effect, in addition to the effect of the solar cell according to the above-mentioned example 1. That is, in Example 3, a solar cell 19 including the p-type semiconductor substrate 4 and the n-type semiconductor layer 18 and a solar cell 20 including the p-type semiconductor layer 3, the Si/SiGe nanopillars, and the n-type semiconductor layer 5 are connected in series via the tunnel junction layer 13 including the n-type semiconductor layer 11 and the p-type semiconductor layer 12. By connecting the two solar cells 19 and 20 in series, a solar cell having an open voltage (electromotive force) higher than that of the solar cell according to the above-mentioned example 1 can be achieved.

### Example 4

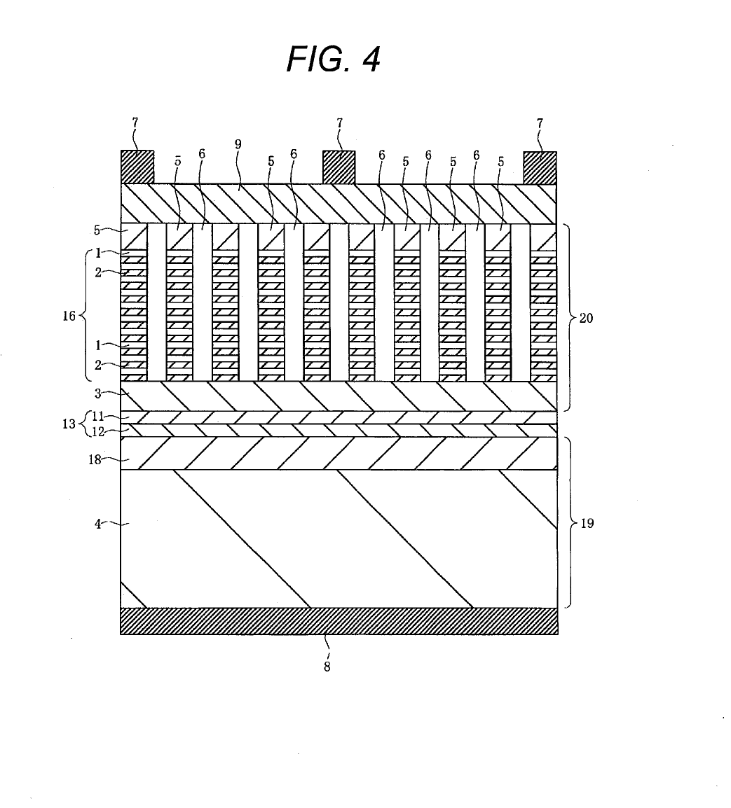

In Example 4 of the present invention, a modification example of the solar cell according to the above-mentioned example 2 is described. In the solar cell according to the above-mentioned example 2, the p-type semiconductor layer 3 is formed on the p-type semiconductor substrate 4. In contrast to this, in a solar cell according to Example 4, an n-layer semiconductor layer 18 having an impurity concentration higher than that of the p-type semiconductor substrate 4 and a tunnel junction layer 13 including an p-layer semiconductor layer 11 and a p-type semiconductor layer 12 are formed between a p-type semiconductor substrate 4 and a p-type semiconductor layer 3. The solar cell according to Example 4 configured in this manner is described with reference to a cross-sectional view of relevant parts of the solar cell illustrated in FIG. 4.

For example, the n-type semiconductor layer 18 having an impurity concentration higher than that of the p-type semiconductor substrate 4 is formed on the primary surface of the p-type semiconductor substrate 4 formed of a Si single crystal. The n-type semiconductor layer 18 may be formed by an impurity diffusion method such as the ion implantation method, the vapor-phase diffusion method, the solid-phase diffusion method, or the like, or by a deposition method such as the CVD method, the sputtering method, the evaporation method, or the like.

The tunnel junction layer 13 including the n-type semiconductor layer 11 and the p-type semiconductor layer is formed on the n-type semiconductor layer 18. A thickness of the tunnel junction layer 13 is, for example, equal to or thinner than 10 nm, and an impurity concentration of each of the n-type semiconductor layer 11 and the p-type semiconductor layer 12 is, for example, 10¹⁹ cm⁻³.

The p-type semiconductor layer 3 is formed on the tunnel junction layer 13. Further, in the similar manner to the above-mentioned example 2, a nanopillar array area 16 constituted with the Si/SiGe nanopillar and an inter-layer insulation film 6 is formed on the p-type semiconductor layer 3, an n-type semiconductor layer 5 is formed only on the upper surfaces of the Si/SiGe nanopillars, and a transparent conductive film 9 is formed on the n-type semiconductor layer 5.

Further, a front surface electrode 7 electrically connected to the n-type semiconductor layer 5 via the transparent conductive film 9 is formed, and a back surface electrode 8 electrically connected to the back surface of the p-type semiconductor substrate 4 is formed on the back surface of the p-type semiconductor substrate 4.

In this manner, the solar cell according to Example 3 has the following effect, in addition to the effect of the solar cell according to the above-mentioned example 2. That is, in Example 4, a solar cell 19 including the p-type semiconductor substrate 4 and the n-type semiconductor layer 18 and a solar cell 20 including the p-type semiconductor layer 3, the Si/SiGe nanopillars, and the n-type semiconductor layer 5 are connected in series via the tunnel junction layer 13 including the n-type semiconductor layer 11 and the p-type semiconductor layer 12. By connecting the two solar cells 19 and 20 in series, a solar cell having an open voltage (electromotive force) higher than that of the solar cell according to the above-mentioned example 3 can be achieved.

### Example 5

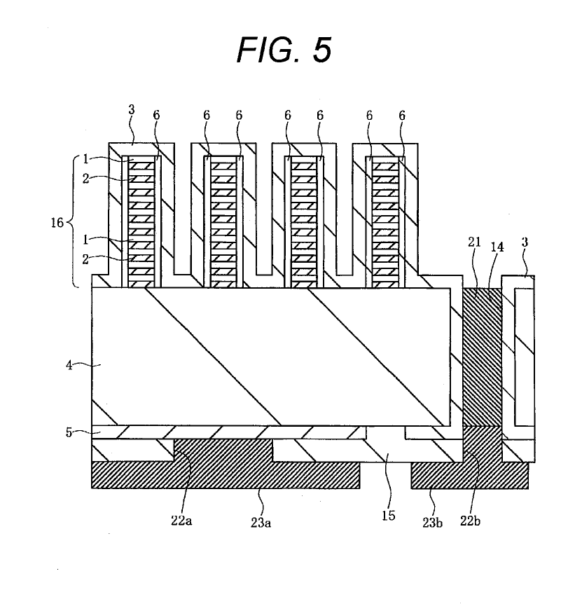

In the solar cells according to the above-mentioned examples 1 to 4, the front surface electrode 7 is formed on a side of the front surface of the solar cell (side of the primary surface of the p-type semiconductor substrate 4), and the back surface electrode 8 is formed on a side of the back surface of the solar cell (side of the back surface opposite to the primary surface of the p-type semiconductor substrate 4). In contrast to this, a solar cell according to Example 5 of the present invention is a so-called backside bonding-type solar cell in which an electrode that blocks the solar light does not exist on a solar light receiving surface. The solar cell according to Example 5, which is configured in this manner, is described with reference to a cross-sectional view of relevant parts of the solar cell illustrated in FIG. 5.

For example, a nanopillar array area 16 exists on the primary surface of a p-type semiconductor substrate 4 formed of, for example, a Si single crystal. The nanopillar array including the plurality of circular column-shaped Si/SiGe nanopillars each constituted with the Si/SiGe superlattice including Si layers 1 and SiGe layers laminated in an alternate manner arranged at predetermined intervals in a two-dimensional array is formed in the nanopillar array area 16. A thickness of each of the Si layer 1 and the SiGe layer 2 is, for example, 5 nm to 6 nm, and a thickness of the nanopillar array area is, for example, 200 nm. A diameter of the Si/SiGe nanopillar is, for example, 30 nm. No impurity is doped in the Si layer 1 and the SiGe layer 2.

The Si/SiGe nanopillar can be manufactured, for example, in the following manner.

Firstly, the Si layer 1 and the SiGe layer 2 constituting the Si/SiGe nanopillar are formed on the primary surface of the p-type semiconductor substrate 4 in an alternate manner by using, for example, the selective epitaxial growth method. Each of the Si layer 1 and the SiGe layer 2 is formed by controlling the Ge composition ratio at the time of growth. Alternatively, the Si layer 1 and the SiGe layer 2 may be deposited on the primary surface of the p-type semiconductor substrate 4 in an alternate manner by using a deposition method such as the CVD method, the sputtering method, or the evaporation method, and then the Si layer 1 and the SiGe layer 2 are crystallized by a thermal treatment to form the Si layer 1 and the SiGe layer 2 constituting the Si/SiGe nanopillar.

Subsequently, the multilayer film including the Si layer 1 and the SiGe layer 2 is processed by, for example, etching with a pattern formed by an electron beam lithography as a mask, etching with a pattern formed by a lithography using ArF, KrF, or the like as a mask, or etching with a nanoimprint or a nanoparticle as a mask, to form a plurality of Si/SiGe nanopillars.

Further, an inter-layer insulation film 6 is formed on side surfaces of the Si/SiGe nanopillars. The inter-layer insulation film 6 is formed of, for example, SiO₂, SiN, SiC, or the like. In order to suppress a carrier recombination generated at a boundary surface of the Si/SiGe nanopillars and the inter-layer insulation film 6, a quality insulation film (not shown) may be formed on surfaces of the Si/SiGe nanopillars by performing an oxidation process before forming the inter-layer insulation film 6. By performing the oxidation process, defects of the Si/SiGe nanopillars can be reduced on the boundary surface of the Si/SiGe nanopillars and the inter-layer insulation film 6, and hence the carrier recombination can be suppressed.

A via hole 14 that penetrates through the p-type semiconductor substrate 4 from the primary surface to the back surface is formed on the p-type semiconductor substrate 4 other than the nanopillar array area 16 where the nanopillar array is formed. For example, the via hole is formed on the p-type semiconductor substrate 4 by forming a pattern by a photolithography and then dry etching by using the pattern as a mask. Alternatively, the via hole 14 may be formed on the p-type semiconductor substrate 4 by using a laser that employs a short pulse laser source that oscillates at nanoseconds or picoseconds. In the case of forming the via hole 14 by using the laser, a laser lithography can be performed in a direct manner, and hence there is an advantage that the photolithography process can be omitted. A buried electrode 21 that is electrically connected to a p-type semiconductor layer 3 is formed inside the via hole 14.

The p-type semiconductor layer 3 is formed on the upper surfaces of the plurality of Si/SiGe nanopillars, on the side surfaces of the plurality of Si/SiGe nanopillars via the inter-layer insulation film 6, on a portion of the primary surface of the p-type semiconductor substrate 4 where the plurality of Si/SiGe nanopillars are not formed, on a side surface of the via hole 14, and on a portion of the back surface of the p-type semiconductor substrate 4 (around the via hole 14). The impurity concentration of the p-type semiconductor layer 3 is higher than that of the p-type semiconductor substrate 4, which is, for example, about 10¹⁸ cm⁻³ to 10²⁰ cm⁻³. The p-type semiconductor layer 3 may be formed, for example, with amorphous Si doped with a p-type impurity by using a deposition method such as the CVD method, the sputtering method, the evaporation method, or the like, or formed by depositing amorphous Si doped with no impurity and then doping a p-type impurity by an impurity diffusion method such as an ion implantation method, a vapor-phase diffusion method, a solid-phase diffusion method, or the like.

An n-type semiconductor layer 5 that is not brought into contact with the p-type semiconductor layer 3 is formed on a portion of the back surface of the p-type semiconductor substrate 4 where the p-type semiconductor layer 3 is not formed. The n-type semiconductor layer 5 may be formed, for example, with amorphous Si doped with a n-type impurity by using a deposition method such as the CVD method, the sputtering method, the evaporation method, or the like, or formed by depositing amorphous Si doped with no impurity and then doping an n-type impurity by an impurity diffusion method such as an ion implantation method, a vapor-phase diffusion method, a solid-phase diffusion method, or the like.

A passivation film 15 is formed on a side of the back surface of the p-type semiconductor substrate 4, to cover the p-type semiconductor layer 3, the n-type semiconductor layer 5, and a portion of the p-type semiconductor substrate 4 that is exposed. The passivation film 15 has a function of suppressing the carrier recombination. The passivation film 15 is formed with, for example, SiO₂, SiN, or the like.

A first contact hole 22a that reaches the n-type semiconductor layer 5 and a second contact hole 22b that reaches the buried electrode 21 buried inside the via hole 14 are formed on the passivation film 15. For example, the first contact hole 22a and the second contact hole 22b are formed on the passivation film 15 by forming a pattern by a photolithography and then dry etching by using the pattern as a mask. Alternatively, the first contact hole 22a and the second contact hole 22b may be formed on the passivation film 15 by using a laser that employs a short pulse laser source that oscillates at nanoseconds or picoseconds.

Further, a first lead electrode 23a that is electrically connected to the n-type semiconductor layer 5 via the first contact hole 22a is formed, and a second lead electrode 23b that is electrically connected to the buried electrode 21 via the second contact hole 22b is formed. The first lead electrode 23a and the second lead electrode 23b are constituted with, for example, Al, Ag, or the like.

In this manner, the solar cell according to Example 5 has the following effect, in addition to the effect of the solar cell according to the above-mentioned example 1. That is, in Example 5, the via hole 14 is formed on the p-type semiconductor substrate 4, and a current generated on a side of the front surface of the solar cell (side of the primary surface of the p-type semiconductor substrate 4) is bypassed to a side of the back surface of the solar cell (side of the back surface of the p-type semiconductor substrate 4) through the buried electrode 21 buried in the via hole 14, and flows to the second lead electrode 23b formed on the side of the back surface of the solar cell. The solar cell according to Example 5 is an approaching method of a structure referred to as a so-called backside bonding cell, with which a light receiving area is substantially increased by forming all electrodes that block the solar light on the side of the back surface of the solar cell, and as a result, a solar cell having higher optical-electrical conversion efficiency can be achieved.

The invention achieved by the inventors of the present invention has been described in detail based on the exemplary embodiments; however, the present invention is not limited to the above-mentioned embodiments, but various modifications may be made without departing from the spirit or scope of the general inventive concept as defined by the appended claims and their equivalents.

For example, it goes without saying that the material of each element, the conductivity type, the manufacturing condition, and the like are not limited to the descriptions of the above-mentioned Examples, but various modifications may be made. Although the descriptions have been given by fixing the conductivity type of the semiconductor substrate and the semiconductor film for the sake of explanation, the conductivity type is not limited to the ones described in the above-mentioned Examples.

### INDUSTRIAL APPLICABILITY

The present invention is suitable for a photovoltaic element such as a solar cell used in a photovoltaic generation.

### REFERENCE SIGNS LIST

1 Si (silicon) layer
2 SiGe (silicon germanium) layer
3 p-type semiconductor layer (first semiconductor layer)
4 p-type semiconductor substrate
5 n-type semiconductor layer (second semiconductor layer)
6 inter-layer insulation film
7 front surface electrode (first electrode)
8 back surface electrode (second electrode)
9 transparent conductive film
11 n-type semiconductor layer (fifth semiconductor layer)
12 p-type semiconductor layer (fourth semiconductor layer)
13 tunnel junction layer
14 via hole
15 passivation film
16 nanopillar array area
17 passivation film
18 n-type semiconductor layer (third semiconductor layer)
19, 20 solar cell
21 buried electrode (fifth electrode)
22a first contact hole
22b second contact hole
23a first lead electrode (third electrode)
23b second lead electrode (fourth electrode)

1. A solar cell, comprising:
a semiconductor substrate of a first conductivity type including a first surface and a second surface opposite to the first surface;
a first semiconductor layer of the first conductivity type formed on the first surface of the semiconductor substrate;
a nanopillar array formed on the first semiconductor layer, the nanopillar array including a plurality of nanopillars arranged at predetermined intervals and connected to the first semiconductor layer;
an inter-layer insulation film formed between adjacent nanopillars of the plurality of nanopillars;
a second semiconductor layer of a second conductivity type different from the first conductivity type formed on the nanopillar array and the inter-layer insulation film and connected to the plurality of nanopillars;
a passivation film formed on the second semiconductor layer;
a first electrode formed on the passivation film, penetrating through the passivation film, and electrically connected to the second semiconductor layer; and
a second electrode formed on the second surface of the semiconductor substrate and electrically connected to the semiconductor substrate, wherein
the plurality of nanopillars is constituted with a Si/SiGe superlattice including Si layers and SiGe layers alternately laminated.

2. The solar cell according to claim 1, wherein a Ge composition ratio of the SiGe layer in the Si/SiGe superlattice is smaller than 0.3.

3. The solar cell according to claim 1, wherein a thickness of each of the Si layer and the SiGe layer is equal to or thinner than 10 nm.

4. The solar cell according to claim 1, wherein a diameter of each of the plurality of nanopillars is in a range from 10 nm to 120 nm.

5. The solar cell according to claim 1, further comprising an insulation film having a function of suppressing a carrier recombination formed between side surfaces of the plurality of nanopillars and the inter-layer insulation film.

6. The solar cell according to claim 1, further comprising, between the semiconductor substrate and the first semiconductor layer:
a third semiconductor layer of the second conductivity type formed on the semiconductor substrate and connected to the semiconductor substrate;
a fourth semiconductor layer of the first conductivity type formed on the third semiconductor layer and connected to the third semiconductor layer; and
a fifth semiconductor layer of the second conductivity type formed on the fourth semiconductor layer and connected to the fourth semiconductor layer, wherein
the fourth semiconductor layer and the fifth semiconductor layer have impurity concentration higher than that of the first semiconductor layer, the second semiconductor layer, and the third semiconductor layer.

7. A solar cell, comprising:
a semiconductor substrate of a first conductivity type including a first surface and a second surface opposite to the first surface;
a first semiconductor layer of the first conductivity type formed on the first surface of the semiconductor substrate;
a nanopillar array formed on the first semiconductor layer, the nanopillar array including a plurality of nanopillars arranged at predetermined intervals and connected to the first semiconductor layer;
a plurality of second semiconductor layers of a second conductivity type different from the first conductivity type formed respectively on upper surfaces of the plurality of nanopillars and connected to the plurality of nanopillars;
an inter-layer insulation film formed between adjacent nanopillars of the plurality of nanopillars and adjacent second semiconductor layers of the plurality of second semiconductor layers;
a transparent conductive film formed on the plurality of second semiconductor layers and the inter-layer insulation film and connected to the plurality of second semiconductor layers;
a first electrode formed on the transparent conductive film and electrically connected to the transparent conductive film; and
a second electrode formed on the second surface of the semiconductor substrate and electrically connected to the semiconductor substrate, wherein
the plurality of nanopillars is constituted with a Si/SiGe superlattice including Si layers and SiGe layers alternately laminated.

8. The solar cell according to claim 7, wherein a Ge composition ratio of the SiGe layer in the Si/SiGe superlattice is smaller than 0.3.

9. The solar cell according to claim 7, wherein thickness of each of the Si layer and the SiGe layer is equal to or thinner than 10 nm.

10. The solar cell according to claim 7, wherein a diameter of each of the plurality of nanopillars is in a range from 10 nm to 120 nm.

11. The solar cell according to claim 7, further comprising an insulation film having a function of suppressing a carrier recombination formed between side surfaces of the plurality of nanopillars and the inter-layer insulation film.

12. The solar cell according to claim 7, further comprising, between the semiconductor substrate and the first semiconductor layer:
a third semiconductor layer of the second conductivity type formed on the semiconductor substrate and connected to the semiconductor substrate;
a fourth semiconductor layer of the first conductivity type formed on the third semiconductor layer and connected to the third semiconductor layer; and
a fifth semiconductor layer of the second conductivity type formed on the fourth semiconductor layer and connected to the fourth semiconductor layer, wherein
the fourth semiconductor layer and the fifth semiconductor layer have impurity concentration higher than that of the first semiconductor layer, the second semiconductor layer, and the third semiconductor layer.

13. A solar cell, comprising:
a semiconductor substrate of a first conductivity type including a first surface and a second surface opposite to the first surface;
a nanopillar array formed on the first surface of the semiconductor substrate, the nanopillar array including a plurality of nanopillars arranged at predetermined intervals and connected to the semiconductor substrate;
an inter-layer insulation film formed on side surfaces of the plurality of nanopillars;
a via hole formed penetrating through the semiconductor substrate from the first surface to the second surface in an area free of the nanopillar array;
a first semiconductor layer of the first conductivity type covering the plurality of nanopillars and the inter-layer insulation film, formed on an exposed portion of the first primary surface of the semiconductor substrate, a side surface of the via hole, and a portion of the second primary surface of the semiconductor substrate surrounding the via hole, and connected to the semiconductor substrate;
a second semiconductor layer of a second conductivity type different from the first conductivity type formed on the second primary surface of the semiconductor substrate and connected to the semiconductor substrate without being connected to the first semiconductor layer;
a passivation film covering the second semiconductor layer and formed on the second primary surface of the semiconductor substrate;
a third electrode formed on the passivation film, penetrating through a first contact hole formed on the passivation film, and electrically connected to the second semiconductor layer; and
a fourth electrode formed on the passivation film, penetrating through a second contact hole formed on the passivation film, and electrically connected to the first semiconductor layer, wherein
the nanopillar array is formed on a side of the first primary surface of the semiconductor substrate,
the third electrode and the fourth electrode are formed on a side of the second primary surface of the semiconductor substrate, and
the plurality of nanopillars is constituted with a Si/SiGe superlattice including Si layers and SiGe layers alternately laminated.

14. The solar cell according to claim 13, further comprising a fifth electrode buried in the via hole.

15. The solar cell according to claim 13, wherein a Ge composition ratio of the SiGe layer in the Si/SiGe superlattice is smaller than 0.3.

16. The solar cell according to claim 13, wherein a thickness of each of the Si layer and the SiGe layer is equal to or thinner than 10 nm.

17. The solar cell according to claim 13, wherein a diameter of each of the plurality of nanopillars is in a range from 10 nm to 120 nm.

18. The solar cell according to claim 13, further comprising an insulation film having a function of suppressing a carrier recombination formed between side surfaces of the plurality of nanopillars and the inter-layer insulation film.
